(19) United States
(12) Patent Application Publication
(10) Pub. No.: US 2025/0349695 A1
(43) Pub. Date: Nov. 13, 2025

(54) SUBSTRATE STRUCTURE AND SEMICONDUCTOR PACKAGE

(71) Applicants: Global Unichip Corporation, Hsinchu (TW); Taiwan Semiconductor Manufacturing Company, Ltd., Hsinchu (TW)

(72) Inventors: Wen-Yi Jian, Hsinchu (TW); Yuan-Hung Lin, Hsinchu (TW); Sheng-Fan Yang, Hsinchu (TW); Yi-Tzeng Lin, Hsinchu (TW); Bo-Yan Li, Hsinchu (TW); Li-Ya Tseng, Hsinchu (TW); Liang-Kai Chen, Hsinchu (TW); Chih-Chiang Hung, Hsinchu (TW)

(73) Assignees: Global Unichip Corporation, Hsinchu (TW); Taiwan Semiconductor Manufacturing Company, Ltd., Hsinchu (TW)

(21) Appl. No.: 18/755,602

(22) Filed: Jun. 26, 2024

(30) Foreign Application Priority Data
May 13, 2024 (TW) 113117527

(51) Int. Cl. H01L 23/498; H01L 23/00; H01L 23/13; H01L 23/528; H01L 23/538; H01L 23/552; H01L 25/065; H01L 25/18

(52) U.S. Cl. CPC H01L 23/49838; H01L 23/13; H01L 23/49822; H01L 23/49833; H01L 23/5286; H01L 23/5386; H01L 23/552; H01L 24/16; H01L 25/0655; H01L 25/18; H01L 2224/16225; H01L 2924/1431

(57) ABSTRACT

A substrate structure includes a substrate, a redistribution structure, and a pad-connection layer. The substrate has a first die region, a second die region, and a spacing region between the first die region and the second die region. The redistribution structure is disposed on the substrate, wherein the redistribution structure includes multiple signal wirings and multiple shielding wirings. The signal wirings and the shielding wirings are alternately disposed in a vertical direction and a lateral direction, and a width of the shielding wiring is within a range of 3.5 times to 4.6 times a width of the signal wiring. The pad-connection layer is disposed on the substrate, and the redistribution structure is located between the pad-connection layer and the substrate, wherein the pad-connection layer includes multiple pad-connection patterns located in the first die region and the second die region.

### CROSS-REFERENCE TO RELATED APPLICATION

This application claims the priority benefit of Taiwan application serial no. 113117527, filed on May 13, 2024. The entirety of the above-mentioned patent application is hereby incorporated by reference herein and made a part of this specification.

### BACKGROUND

### Technical Field

The disclosure relates to a package-related structure, and in particular to a substrate structure and semiconductor package.

### Description of Related Art

With the advancement of semiconductor manufacturing technology, the performance of chip devices is increasingly improving. The industry also has higher requirements for the processing speed of chip devices. In order to implement highly efficient processing performance, related technologies have been proposed to stack dies into three-dimensional packages, in which the interface design between dies is also continuously improving. For example, in high-density designs, controlling crosstalk between signals becomes an important issue.

### SUMMARY

The disclosure provides a substrate structure with ideal signal transmission performance.

The disclosure provides a semiconductor package that controls crosstalk between signals within a required range.

The substrate structure of the disclosure includes a substrate, a redistribution structure, and a pad-connection layer. The substrate has a first die region, a second die region, and a spacing region extending between the first die region and the second die region. The redistribution structure is disposed on the substrate. The redistribution structure includes multiple signal wirings and multiple shielding wirings. The signal wirings and the shielding wirings are alternately disposed in a vertical direction and in a lateral direction, and a width of the shielding wiring falls within a range of 3.5 times to 4.6 times a width of the signal wiring. The pad-connection layer is disposed on the substrate, and the redistribution structure is located between the pad-connection layer and the substrate. The pad-connection layer includes multiple pad-connection patterns located in the first die region and the second die region.

The substrate structure of the disclosure includes a substrate, a redistribution structure, and a pad-connection layer. The substrate has a first die region, a second die region, and a spacing region extending between the first die region and the second die region. The redistribution structure is disposed on the substrate. The pad-connection layer is disposed on the substrate, and the redistribution structure is located between the pad-connection layer and the substrate. The pad-connection layer includes multiple pad-connection patterns located in the first die region and the second die region and multiple shielding strips extending between the first die region and the second die region and crossing the spacing region.

The semiconductor package of the disclosure includes a substrate structure, a first die, and a second die. The substrate structure includes a substrate, a redistribution structure, and a pad-connection layer. The substrate has a first die region, a second die region, and a spacing region extending between the first die region and the second die region. The redistribution structure is disposed on the substrate. The pad-connection layer is disposed on the substrate, and the redistribution structure is located between the pad-connection layer and the substrate. The pad-connection layer includes multiple pad-connection patterns located in the first die region and the second die region and multiple shielding strips extending between the first die region and the second die region and crossing the spacing region. A first die is bonded to the substrate structure in the first die region. A second die is bonded to the substrate structure in the second die region. The first die and the second die are separated by the spacing region.

Based on the above, in the substrate structure of the embodiments of the disclosure, the shielding strips are disposed on the pad-connection layer of the redistribution structure and/or the widened shielding wirings are disposed on the signal wirings of the redistribution structure to control signal crosstalk between the signal wirings within an appropriate range, thereby implementing high signal processing efficiency. Since the shielding strips and the widened shielding wirings both do not require additional processes to manufacture, the shielding strips and the widened shielding wirings may be manufactured during the existing process, thereby not causing a burden on the process.

### BRIEF DESCRIPTION OF THE DRAWINGS

FIG. 1 is a schematic partial top view of a substrate structure according to an embodiment of the disclosure.

FIG. 2 is a schematic cross-sectional view of the substrate structure of FIG. 1 along a line I-I.

FIG. 3 is a schematic cross-sectional view of the substrate structure of FIG. 1 along a line II-II.

FIG. 4 is a schematic view of a semiconductor package according to an embodiment of the disclosure.

### DESCRIPTION OF THE EMBODIMENTS

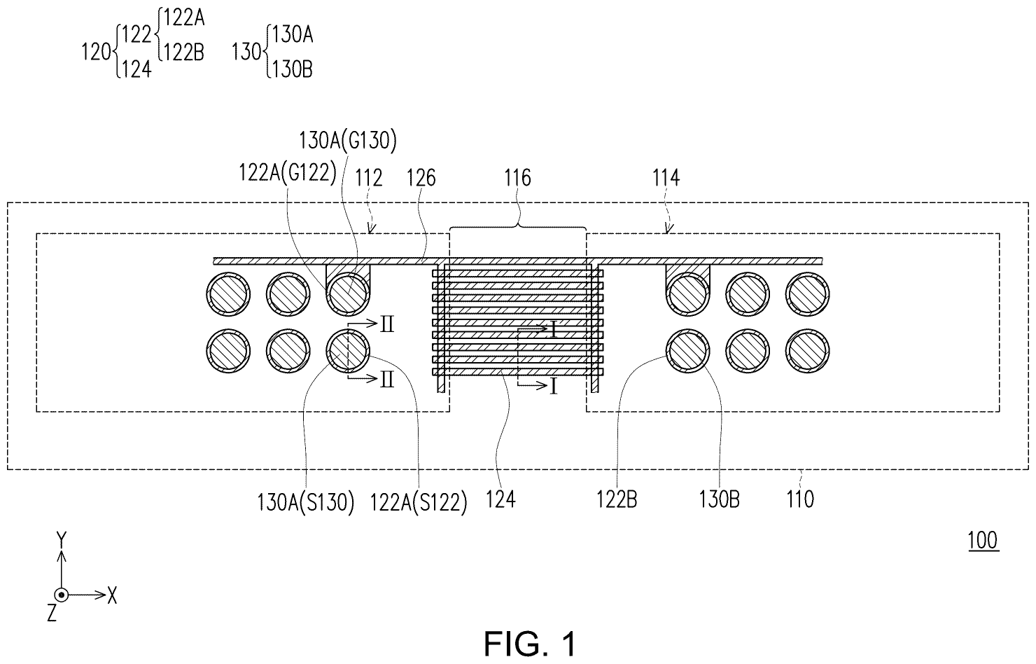

FIG. 1 is a schematic partial top view of a substrate structure according to an embodiment of the disclosure. A substrate structure 100 in FIG. 1 includes a substrate 110 and a pad- connection layer 120 disposed on the substrate 110, and FIG. 1 only shows a part of the pad-connection layer 120. The substrate structure 100 may be understood as an interposer in the semiconductor package and may be configured to implement signal connection between multiple semiconductor dies and may also be configured for signal connection between the semiconductor die and the package substrate. In other words, the substrate structure 100 may provide signal transmission/connection in a lateral direction (such as an X direction) and signal transmission/connection in a vertical direction (such as a Z direction). In addition, the substrate structure 100 may further include multiple pads 130 disposed on the pad-connection layer 120. The pads 130 may be configured to enable other components (such as semiconductor dies or the similar) to be bonded to the substrate structure 100 in conjunction with suitable bonding members.

In some embodiments, the substrate 110 of the substrate structure 100 may be a silicon substrate. The substrate 110 may have sufficient mechanical strength to support components such as dies disposed thereon in subsequent applications. In some embodiments, circuit elements such as transistors may not be provided on the substrate 110 or in the substrate 110, but designed conductive features may be provided on the substrate 110 or in the substrate 110 to establish electrical transmission paths between multiple components. For example, the pad-connection layer 120 may be understood as an example of the designed conductive feature provided on the substrate 110. In practical applications, the substrate 110 may be bonded to multiple semiconductor dies or similar components, and thus may have a first die region 112 and a second die region 114. At the same time, the substrate 110 may further have a spacing region 116 between the first die region 112 and the second die region 114. In some embodiments, the first die region 112 and the second die region 114 may be planned to have corresponding sizes to the semiconductor dies or similar components to be bonded, while the spacing region 116 is a region requested to be reserved based on process factors during assembly of the substrate and the semiconductor dies. In other words, the spacing region 116 cannot overlap with the semiconductor dies or similar components.

The pad-connection layer 120 may include multiple pad-connection patterns 122 and multiple shielding strips 124. The pad-connection layer 120 may be composed of a patterned metal material layer. The pad-connection patterns 122 and the shielding strips 124 are on the same layer and formed by the same process. The materials of the pad-connection patterns 122 and the shielding strips 124 include copper, gold, aluminum, nickel, alloys thereof, or combinations of the above materials. In addition, the pad-connection layer 120 may further include a reference ground line 126 configured to connect to ground potential. The reference ground line 126 may connect to the shielding strips 124 and one or a part of the pad-connection patterns 122.

In some embodiments, the pad-connection pattern 122 connected to the reference ground line 126 may be referred to as a reference-ground pattern G122, and the other pad-connection patterns 122 may be configured to transmit signals and referred to as signal-connection patterns S122. For clarity of the drawing, FIG. 1 only schematically marks one reference-ground pattern G122 and one signal-connection pattern S122 on a pad-connection pattern 122A located in the first die region 112. In addition, as shown in FIG. 1, the shielding strips 124 and the reference-ground patterns G122 may be physically and electrically connected to each other through the reference ground line 126, but not limited thereto.

In some embodiments, the substrate structure 100 is configured to enable multiple semiconductor dies or similar components to be bonded thereto, and specifically, the semiconductor dies or similar components may be bonded to the pads 130 through suitable bonding members (not shown in FIG. 1, but may include micro bumps or the similar). According to the disposal location, the pads 130 may include a pad 130A located in the first die region 112 and a pad 130B located in the second die region 114. In addition, the pad-connection patterns 122 corresponding to the individual pad 130 also include the pad-connection pattern 122A located in the first die region 112 and a pad-connection pattern 122B located in the second die region 114. In some embodiments, the dimensions of the pads 130 and the corresponding pad-connection patterns 122 may correspond to each other, or one may be larger than the other. The number and arrangement of the pads 130A and the pads 130B are related to the design of the corresponding semiconductor dies or similar components. Therefore, the number and arrangement of the pads 130A and the pads 130B may be different or may be the same. For clarity of the drawing, FIG. 1 only shows six pads 130A and six pads 130B, and the number of individual features shown in the drawing is for illustration only and not for limitation.

The shielding strips 124 extend between the first die region 112 and the second die region 114 and cross the spacing region 116. In some embodiments, the ends of each of the shielding strips 124 may respectively overlap the first die region 112 and the second die region 114. The shielding strips 124 may be connected to the reference ground line 126, and the reference ground line 126 may be connected to the reference-ground pattern G122. In some embodiments, the pad 130 corresponding to the reference-ground pattern G122 may be configured for grounding and referred to as a reference ground pad G130, and the other pads 130 configured to transmit signals may be referred to as signal pads S130. The shielding strips 124 and the reference ground pad G130 are physically and electrically connected to each other. However, the shielding strips 124 and the signal pads S130 are physically and electrically separated and are electrically independent conductive features. In addition, the shielding strips 124 may be arranged approximately parallel to each other, but not limited thereto. For clarity of the drawing, the reference ground pad G130 and the signal pad S130 are marked on a part of the pads 130A located in the first die region 112, but the pad 130B located in the second die region 114 may also have a similar structure and connection relationship.

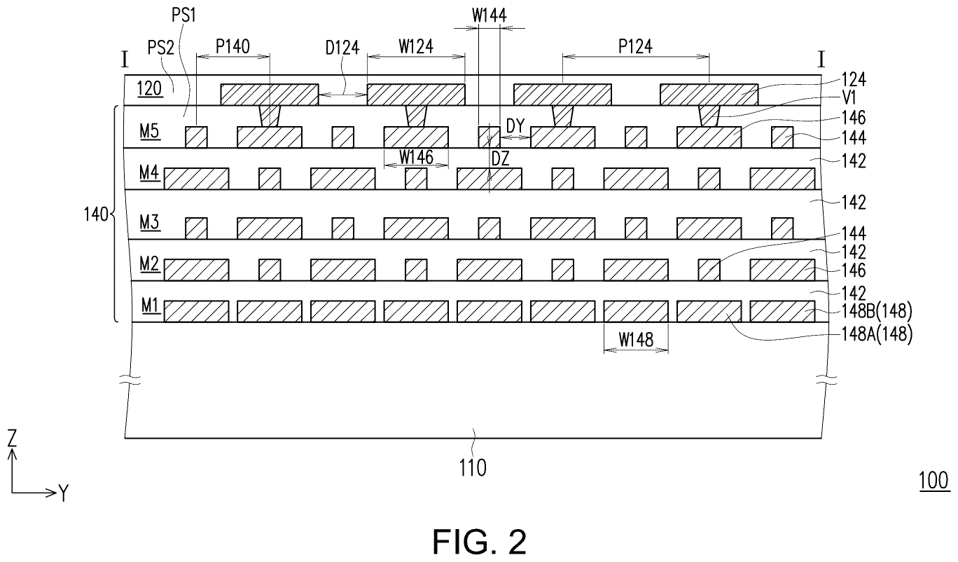

FIG. 2 is a schematic cross-sectional view diagram of the substrate structure of FIG. 1 along a line I-I. As shown in FIG. 2, the substrate structure 100 further includes a redistribution structure 140. The redistribution structure 140 is disposed on the substrate 110. The redistribution structure 140 includes multiple wiring layers M1 to M5 sequentially stacked between the substrate 110 and the pad-connection layer 120, wherein the wiring layer M1 is closest to the substrate 110, and the wiring layer M5 is farthest from the substrate 110. In order to separate different conductive features, the redistribution structure 140 further includes an interlayer insulator 142, wherein the interlayer insulator 142 is disposed on the substrate 110 and extends between the redistribution structure 140 and the pad-connection layer 120. In addition, the substrate structure 100 further includes a protection layer PS1 covering the wiring layer M5 and a protection layer PS2 covering the pad-connection layer 120. Specifically, the interlayer insulator 142, the protection layer PS1, and the protection layer PS2 may separate conductor features formed by the wiring layers M1 to M5 and the pad-connection layer 120 to maintain electrical conduction paths required by the individual conductor features. The number of the wiring layers M1 to M5 may be determined according to different designs or applications and is illustrated to be five layers in the embodiment, which is only configured to provide a possible example and is not configured to limit the number of the wiring layers M1 to M5.

The wiring layers M1 to M5 of the redistribution structure 140 are respectively patterned conductive metal layers. The materials thereof include copper, gold, aluminum, nickel, alloys thereof, or combinations of the above materials. In some embodiments, the wiring layers M1 to M5 may be formed through a damascene process, such as a single damascene process, a dual damascene process, or a similar process. In some embodiments, the interlayer insulator 142 may be formed of a dielectric material, such as silicon oxide, phosphosilicate glass (PSG), borosilicate glass (BSG), boron-doped phosphosilicate glass (BPSG), similar oxides, silicon nitride, or similar nitrides.

The redistribution structure 140 includes multiple underlayer wirings 148 in the wiring layer M1 closest to the substrate 110, wherein the underlayer wirings 148 are disposed on the substrate 110. The underlayer wirings 148 may include ground wirings 148A and power source wirings 148B which are alternately arranged. In some embodiments, each of the underlayer wirings 148 has approximately a width W148. In other words, the width W148 of the ground wiring 148A and the width W148 of the power source wiring 148B are approximately the same.

In some embodiments, the wiring layers M2 to M5 are configured to distribute electrical conduction paths according to required circuit designs, so wiring arrangement designs of the wiring layers M2 to M5 may be different from a wiring arrangement design of the wiring layer M1.

As shown in FIG. 2, the redistribution structure 140 may include the signal wirings 144 and the shielding wirings 146. The signal wirings 144 and the shielding wirings 146 may be the wirings of the wiring layers M2 to M5. The signal wirings 144 and the shielding wirings 146 are alternately disposed in the vertical direction (such as the Z direction) and in the lateral direction (such as a Y direction). For example, each of the wiring layers M2 to M5 may include the signal wirings 144 and the shielding wirings 146. Taking the wiring layer M5 as an example, in the Y direction, the wiring adjacent to each of the signal wirings 144 is the shielding wiring 146, and the wiring adjacent to each of the shielding wirings 146 is the signal wiring 144. Therefore, the signal wirings 144 and the shielding wirings 146 in the wiring layer M5 are alternately arranged along the Y direction, and there is no arrangement in which two signal wirings 144 are closely adjacent to each other. The wiring layer M2 to the wiring layer M4 also have the same wiring arrangement.

In addition, in the Z direction, the signal wirings 144 of the wiring layer M5 and the shielding wirings 146 of the wiring layer M4 are disposed correspondingly, and the shielding wirings 146 of the wiring layer M5 and the signal wirings 144 of the wiring layer M4 are disposed correspondingly. In some embodiments, in the Z direction, one of the signal wirings 144 of the wiring layer M5, one of the shielding wirings 146 of the wiring layer M4, one of the signal wirings 144 of the wiring layer M3, and one of the shielding wirings 146 of the wiring layer M2 may be center aligned with each other. Similarly, in the Z direction, one of the shielding wirings 146 of the wiring layer M5, one of the signal wirings 144 of the wiring layer M4, one of the shielding wirings 146 of the wiring layer M3, and one of the signal wirings 144 of the wiring layer M2 may be center aligned with each other. In addition, the signal wirings 144 and the shielding wirings 146 of the wiring layer M2 may be respectively center aligned with the underlayer wirings 148 of the wiring layer M1. Furthermore, the ground wirings 148A and the power source wirings 148B of the wiring layer M1 are alternately disposed in the lateral direction (such as the Y direction), and in the vertical direction (such as the Z direction), each of the ground wirings 148A and one of the signal wirings 144 of the wiring layer M2 are disposed correspondingly, and each of the power source wirings 148B and one of the shielding wirings 146 of the wiring layer M2 are disposed correspondingly. The above arrangement layout is only for illustration. In other embodiments, any wiring may be selectively designed as a turning wiring, and a section thereof may conform to the above layout relationship, but the entire wiring is not limited to conforming to the above relationship.

Under the wiring arrangement of FIG. 2, each of the signal wirings 144 in the wiring layer M2 to the wiring layer M4 is adjacent to the corresponding shielding wiring 146 in the vertical direction (Z direction) and in the lateral direction (Y direction). In this way, the signal wirings 144 configured to transmit signals are not arranged closely adjacent to each other, which helps to reduce crosstalk between the signal wirings 144 to achieve ideal signal transmission performance.

In some embodiments, the signal wiring 144 has approximately a width W144, the shielding wiring 146 has approximately a width W146, and the width W146 of the shielding wiring 146 is greater than the width W144 of the signal wiring 144. The coupling capacitance and coupling inductance between the wirings may determine the power sum near end cross talk (PSNEXT) of the signal wirings 144. When the width W146 of the shielding wiring 146 is insufficient, the PSNEXT may not be improved ideally. In some embodiments, the width W146 of the shielding wiring 146 may fall within a range of 3.5 times to 4.6 times the width W144 of the signal wiring 144, which may also be understood as 3.5×W144<W146<4.6×W144. In some embodiments, the width W144 of the signal wiring 144 may be determined according to process conditions and design requirements. For example, the width W144 may be set to about 0.8 microns in some high-density applications, but not limited thereto. When the substrate structure 100 is applied to a lower-density design, the width W144 may be greater than 0.8 microns, and when the substrate structure 100 is applied to a higher-density design, the width W144 may be less than 0.8 microns.

The shielding wirings 146 are, for example, grounded wirings and may be used to shield coupling between the adjacent signal wirings 144 and reduce crosstalk between the signal wirings 144. In this embodiment, besides the shielding wirings 146 being disposed around the signal wirings 144, the shielding wirings 146 are further widened to further improve the shielding capability and implement high-quality electrical transmission performance. In addition, in this embodiment, in the vertical direction (Z direction), each of the signal wirings 144 and the adjacent shielding wiring 146 are separated by a vertical distance DZ, and in the lateral direction (Y direction), each of the signal wirings 144 and the adjacent shielding wiring 146 are separated by a lateral distance DY. The vertical distance DZ and the lateral distance DY may be designed to control the load capacitance withstood by the signal wiring 144 and the shielding effect provided by the shielding wiring 146 under ideal conditions. Under the fixed wiring space condition, when the vertical distance DZ and the lateral distance DY are too large, the width W146 of the shielding wiring 146 becomes smaller, and the shielding effect of the shielding wiring 146 cannot be effectively exerted; and when the vertical distance DZ and lateral distance DY are too small, the shielding wiring 146 may cause excessive loading on the signal wiring 144. In some embodiments, neither the vertical distance DZ nor the lateral distance DY may be less than 0.8 microns. In some embodiments, the lateral distance DY may fall within a range of 1.5 times to 1.8 times the vertical distance DZ, which may also be understood as 1.5×DZ≤DY≤1.8×DZ. In addition, as shown in FIG. 2, the shielding strips 124 of the pad-connection layer 120

may be disposed corresponding to the shielding wirings 146 of the wiring layer M5. In some embodiments, referring to FIG. 1, the extension trajectory of the shielding wirings 146 may generally conform to the extension trajectory of the shielding strips 124, that is, extending between the first die region 112 and the second die region 114 and crossing the spacing region 116. Referring back to FIG. 2, in some embodiments, each of the shielding strips 124 and the nearest adjacent wiring of the redistribution structure 140 may be center aligned. For example, each of the shielding strips 124 of the pad-connection layer 120 may be disposed above one of the shielding wirings 146 of the wiring layer M5, and each of the shielding strips 124 and one of the shielding wirings 146 in the wiring layer M5 may be center aligned. In some embodiments, a spacing distance D124 between the shielding strips 124 may be greater than the width W144 of the signal wiring 144. In addition, a pitch P124 of the shielding strips 124 may be approximately equal to twice a wiring pitch P140 of the redistribution structure 140, but not limited thereto.

The shielding strip 124 may be connected to the redistribution structure 140 through a via V1 and specifically connected to the nearest adjacent shielding wiring 146 (that is, the corresponding shielding wiring 146 in the wiring layer M5) through the via V1. In some embodiments, all the shielding wirings 146 and all the shielding strips 124 are grounded. The disposal of the shielding strips 124 may shield crosstalk between the signal wirings 144 in the wiring layer M5, so that even though there are no shielding wirings 146 directly above the signal wirings 144 in the wiring layer M5 (viewed in the Z direction), there is still no obvious crosstalk to provide ideal signal transmission performance.

In some embodiments, the shielding strip 124 has approximately a width W124, and the width W124 of the shielding strip 124 may be greater than a width of any wiring of the redistribution structure 140. For example, the width W124 of the shielding strip 124 is 1.4 times to 1.6 times the width W146 of the nearest adjacent shielding wiring 146, which may also be understood as 1.4×W146≤W124≤1.6×W146. The widened shielding wiring 146 and shielding strip 124 can provide enhanced shielding capabilities, so that the signal wiring 144 has ideal signal transmission performance. In addition, the widening of the shielding wiring 146 and the shielding strip 124 may be configured to avoid causing excessive loading on the signal wiring 144, thereby helping to implement ideal signal transmission performance.

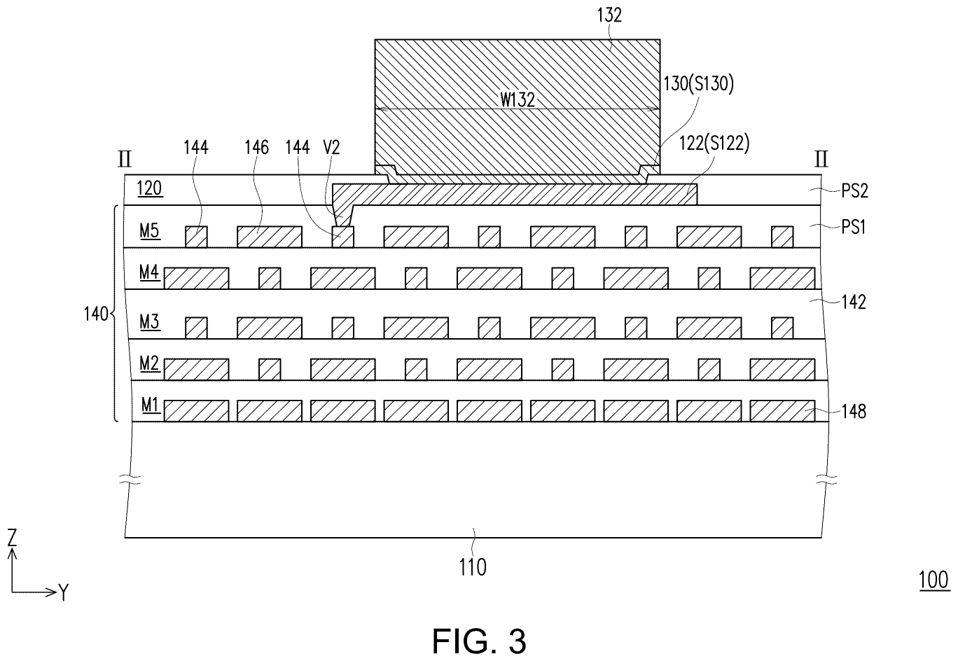

FIG. 3 is a schematic cross-sectional view diagram of the substrate structure of FIG. 1 along a line II-II. Components shown in FIG. 3 are mostly the same as components shown in FIG. 2, so the components marked with the same reference numerals in the two drawings may be cross-referenced. The cross-sectional structure of FIG. 3 schematically shows the connection relationship corresponding to the signal pad S130 and the corresponding signal-connection pattern S122, and the connection relationship between the reference ground pad G130 and the corresponding reference-ground pattern G122 may also have similar features. As shown in FIG. 3, the pad-connection pattern 122 (signal-connection pattern S122) in the pad-connection layer 120 is connected to one of the signal wirings 144 through another via V2. In addition, the pad 130 (signal pad S130) may be disposed on the pad-connection pattern 122 (signal-connection pattern S122). In some embodiments, the pad 130 (signal pad S130) may be further provided with a bonding member 132 thereon. The bonding member 132 may be a micro bump, and a width W132 of the bonding member 132 may approximately fall in a range of about 10 something microns to 30 microns, but not limited thereto. The pad-connection pattern 122 (signal-connection pattern S122) in FIG. 3 and the shielding strips 124 in FIG. 2 are on the same layer, that is, the pad-connection layer 120, and are both disposed above the wiring layer M5 of the redistribution structure 140, and the bonding member 132 is connected to the pad-connection pattern 122 (signal connection pattern S122) through the pad 130 (signal pad S130). The pad-connection patterns 122 and the shielding strips 124 may be formed in the same process steps. In other words, the manufacturing of the shielding strips 124 of the pad-connection layer 120 is integrated into the inherent process of the substrate structure 100, so no additional process is required.

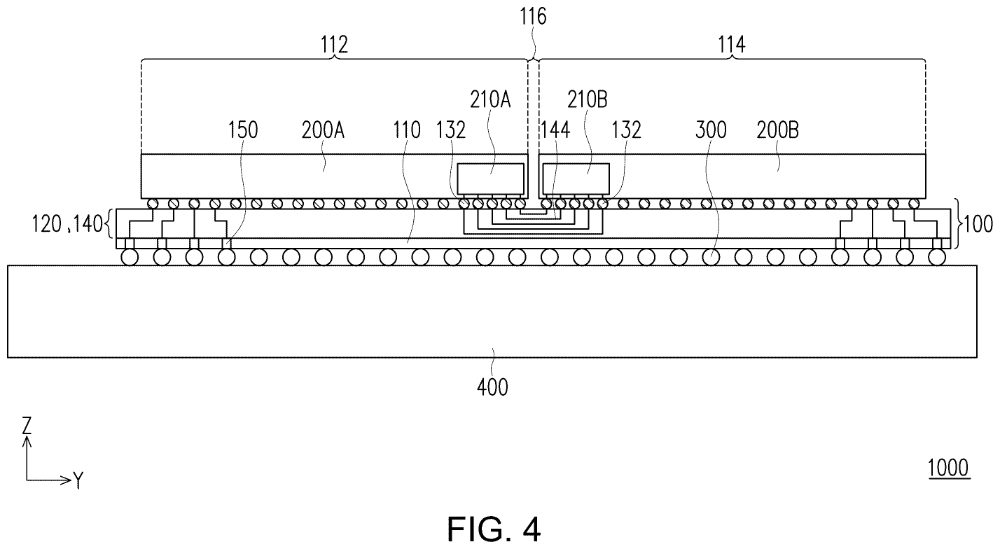

FIG. 4 is a schematic diagram of a semiconductor package according to an embodiment of the disclosure. A semiconductor package 1000 in FIG. 4 at least includes the substrate structure 100, a first die 200A, and a second die 200B. Partial features of the substrate structure 100 may be referred to the substrate structure in FIG. 1 and FIG. 2, and the illustration contents in

FIG. 1 and FIG. 2 may also be incorporated into the semiconductor package 1000 of this embodiment. For example, the substrate structure 100 may include the substrate 110, multiple redistribution structures 140, the bonding member 132, and the pad-connection layer 120. For clarity of the drawing, FIG. 4 only schematically shows the redistribution structures 140 and the pad-connection layer 120 and omits the pads 130. However, features of these components may be referred to the relevant illustrations of FIG. 1, FIG. 2, and FIG. 3. In this embodiment, the substrate 110 may have the first die region 112, the second die region 114, and the spacing region 116 extending between the first die region 112 and the second die region 114. The first die 200A and the second die 200B are respectively bonded to the substrate structure 100 in the first die region 112 and the second die region 114, and the first die 200A and the second die 200B are separated by the spacing region 116. Referring to FIG. 1 to FIG. 4, the first die 200A may be bonded to the bonding member 132 disposed in the first die region 112, and the second die 200B may be bonded to the bonding member 132 disposed in the second die region 114. The profile of the first die 200A projected onto the substrate 110 along the vertical direction (Z direction) may enclose to form the first die region 112, and the profile of the second die 200B projected onto the substrate 110 along the vertical direction (Z direction) may enclose to form the second die region 114. The first die 200A and the second die 200B may not overlap, and the spacing region 116 must be at least partially exposed.

One of the first die 200A and the second die 200B may be a logic die, which may be a central processing unit (CPU) die, a graphics processing unit (GPU) die, a micro control unit (MCU) die, a base band (BB) die, an application processor (AP) die, etc. The other one of the first die 200A and the second die 200B may be a memory die, which may be a static random access memory (SRAM) die, a dynamic random access memory (DRAM) die, a resistive random access memory (RRAM) die, etc. In addition, the first die 200A and the second die 200B may also both be logic dies.

The first die 200A and the second die 200B may be in signal communication with each other through the conductive features in the substrate structure 100. In some embodiments, the first die 200A and the second die 200B respectively have interface circuits disposed therein. For example, the first die 200A has an interface circuit 210A, and the second die 200B has an interface circuit 210B. The interface circuit 210A and the interface circuit 210B may include a Glink-3D interface circuit or a UCIe interface circuit, but not limited thereto. The interface circuit 210A may be in signal communication with a pad (not shown) on the surface of the first die 200A, and the pad on the surface of the first die 200A may be connected to the bonding member 132, so that the interface circuit 210A may be in signal communication with the redistribution structure 140 in the substrate structure 100. Similarly, the interface circuit 210B of the second die 200B may be in signal communication with the redistribution structure 140 in the substrate structure 100 through the corresponding bonding member 132. The signal wiring 144 in the redistribution structure 140 may provide a signal transmission path, so that the interface circuit 210A and the interface circuit 210B are in signal communication with each other. In other words, the interface circuit 210A of the first die 200A and the interface circuit 210B of the second die 200B may implement die-to-die signal communication through the redistribution structure 140.

In this embodiment, the semiconductor package 1000 further includes a bonding bump 300 and a package substrate 400. The bonding bump 300 is disposed on a side of the substrate 110 opposite to the redistribution structure 140. The bonding bump 300 in some embodiments may include a C4 bump, but not limited thereto. In order to transmit electrical signals from the redistribution structure 140 of the substrate structure 100 to the bonding bump 300, the substrate structure 100 may further include a substrate through hole 150 that runs through the substrate 110, wherein the substrate through hole 150 may be connected between the redistribution structure 140 and the bonding bump 300. The bonding bump 300 is configured to bond the substrate structure 100 to the package substrate 400. The package substrate 400 may include a circuit board or other substrates that may have circuit layouts. In some embodiments, the semiconductor package 1000 is a three-dimensional packaging structure, such as chip-on-wafer-on-substrate (CoWoS) package, wherein the substrate structure 100 may be, for example, understood as an interposer or a similar structure, but not limited thereto.

As element density of a semiconductor device continues to increase, the number of signal channels of the interface circuit 210A and the interface circuit 210B also increases accordingly. Certainly, the corresponding signal wirings 144 are bound to increase. In the limited wiring space, crosstalk between the signal wirings 144 often leads to unsatisfactory signal transmission performance. In this embodiment, as shown in FIG. 1 to FIG. 3, the shielding wirings 146 are disposed in the wiring layers M2 to M5 that correspond to the signal wirings 144 in the redistribution structure 140, and the shielding strips 124 are disposed in the pad-connection layer 120. The shielding wirings 146 and the shielding strips 124 can effectively suppress crosstalk between the signal wirings 144, so that signal transmission performance between the first die 200A and the second die 200B can be optimized.

The wiring design of the substrate structure 100 may be applied to products with high data transmission rates, such as 4 Gbps, 8 Gbps, 12 Gbps, 16 Gbps, 17.2 Gbps, etc. When applying the substrate structure 100 with the shielding wirings 146 and the shielding strips 124 to the products with high data transmission rates, an eye diagram obtained can achieve a jitter of less than 4 ps, and an eye width of greater than 0.931 UI.

In summary, in the substrate structure of the embodiments of the disclosure, the shielding strips are disposed in the pad-connection layer, and the shielding wirings are disposed between the signal wirings between the pad-connection layer and the substrate. The shielding strips may provide shielding effects between the signal wirings closest to the pad-connection layer, and the shielding wirings may provide shielding effects between other signal wirings. Therefore, the substrate structure can provide good signal transmission performance and is helpful for application in the products with high data transmission rates. In the semiconductor package of the embodiment of the disclosure, the dies are bonded to the substrate structure, and the signal wirings configured for signal communication between the dies are disposed in the substrate structure, thereby implementing a multi-die integrated package. In addition, in the semiconductor package of the embodiment of the disclosure, the substrate structure has the shielding wirings and the shielding strips corresponding to the signal wirings. Therefore, the signal wirings can provide good signal transmission performance to meet the requirement of high transmission rates.

What is claimed is:

1. A substrate structure, comprising:
a substrate, having a first die region, a second die region, and a spacing region extending between the first die region and the second die region;
a redistribution structure, disposed on the substrate, wherein the redistribution structure comprises a plurality of signal wirings and a plurality of shielding wirings, the signal wirings and the shielding wirings are alternately disposed in a vertical direction and in a lateral direction, and a width of the shielding wiring falls within a range of 3.5 times to 4.6 times a width of the signal wiring; and
a pad-connection layer, disposed on the substrate, wherein the redistribution structure is located between the pad-connection layer and the substrate, and the pad-connection layer comprises a plurality of pad-connection patterns located in the first die region and the second die region.

2. The substrate structure according to claim 1, wherein the pad-connection layer further comprises a plurality of shielding strips extending between the first die region and the second die region and crossing the spacing region.

3. The substrate structure according to claim 2, wherein a width of the shielding strip is 1.4 times to 1.6 times a width of the nearest adjacent shielding wiring.

4. The substrate structure according to claim 2, wherein the shielding strip is connected the nearest adjacent shielding wiring through a via.

5. The substrate structure according to claim 2, further comprising a reference ground pad disposed on the pad-connection layer, wherein the shielding strips and the reference ground pad are physically and electrically connected to each other.

6. The substrate structure according to claim 1, wherein the signal wirings and the shielding wirings alternately disposed in the vertical direction are separated by a vertical distance, the signal wirings and the shielding wirings alternately disposed in the lateral direction are separated by a lateral distance, and the lateral distance falls within a range of 1.5 times to 1.8 times the vertical distance.

7. The substrate structure according to claim 6, wherein the lateral distance is not less than 0.8 microns.

8. The substrate structure according to claim 1, wherein the redistribution structure further comprises a plurality of underlayer wirings, the underlayer wirings are disposed on the substrate, and the signal wirings and the shielding wirings are located between the underlayer wirings and the pad-connection layer, wherein the underlayer wirings have a same width.

9. The substrate structure according to claim 8, wherein the underlayer wirings further comprise a plurality of ground wirings and a plurality of power source wirings, wherein the ground wirings and the power source wirings are alternately disposed in the lateral direction, each of the ground wirings and one of the signal wirings are correspondingly disposed in the vertical direction, and each of the power source wirings and one of the shielding wirings are correspondingly disposed in the vertical direction.

10. A substrate structure, comprising:
a substrate, having a first die region, a second die region, and a spacing region extending between the first die region and the second die region;
a redistribution structure, disposed on the substrate; and
a pad-connection layer, disposed on the substrate, wherein the redistribution structure located between the pad-connection layer and the substrate, and the pad-connection layer comprises a plurality of pad-connection patterns located in the first die region and the second die region and a plurality of shielding strips extending between the first die region and the second die region and crossing the spacing region.

11. The substrate structure according to claim 10, wherein the shielding strip is connected to the redistribution structure through a via.

12. The substrate structure according to claim 10, further comprising a reference ground pad disposed on the pad-connection layer, wherein the shielding strips and the reference ground pad are physically and electrically connected to each other.

13. The substrate structure according to claim 10, wherein a width of the shielding strip is greater than a width of any wiring of the redistribution structure.

14. The substrate structure according to claim 10, wherein a pitch of the shielding strips is approximately twice a wiring pitch of the redistribution structure.

15. The substrate structure according to claim 10, wherein a width of each of the shielding strips is 1.4 times to 1.6 times a width of a nearest adjacent shielding wiring of the redistribution structure.

16. The substrate structure according to claim 10, wherein the redistribution structure comprises a plurality of underlayer wirings, the underlayer wirings are disposed on the substrate, and the underlayer wirings have a same width.

17. The substrate structure according to claim 16, wherein the underlayer wirings comprise a plurality of ground wirings and a plurality of power source wirings, wherein the ground wirings and the power source wirings are alternately disposed in a lateral direction.

18. A semiconductor package, comprising:
a substrate structure, comprising:
a substrate, having a first die region, a second die region, and a spacing region extending between the first die region and the second die region;
a redistribution structure, disposed on the substrate; and
a pad-connection layer, disposed on the substrate, wherein the redistribution structure is located between the pad-connection layer and the substrate, and the pad-connection layer comprises a plurality of pad-connection patterns located in the first die region and the second die region and a plurality of shielding strips extending between the first die region and the second die region and crossing the spacing region;
a first die, bonded to the substrate structure in the first die region; and
a second die, bonded to the substrate structure in the second die region, wherein the first die and the second die are separated by the spacing region.

19. The semiconductor package according to claim 18, wherein the redistribution structure comprises a plurality of signal wirings and a plurality of shielding wirings, and the signal wirings and the shielding wirings are alternately disposed in a vertical direction and in a lateral direction.

20. The semiconductor package according to claim 19, wherein a width of the shielding wiring falls within a range of 3.5 times to 4.6 times a width of the signal wiring.

21. The semiconductor package according to claim 19, wherein a width of the shielding strip is 1.4 times to 1.6 times a width of the nearest adjacent shielding wiring in the redistribution structure.

22. The semiconductor package according to claim 19, wherein the shielding strip is connected to the nearest adjacent shielding wiring in the redistribution structure through a via.

23. The semiconductor package according to claim 19, wherein the substrate structure further comprises a reference ground pad disposed on the pad-connection layer, wherein the shielding strips and the reference ground pad are physically and electrically connected to each other.

24. The semiconductor package according to claim 19, wherein the signal wirings and the shielding wirings alternately disposed in the vertical direction are separated by a vertical distance, the signal wirings and the shielding wirings alternately disposed in the lateral direction are separated by a lateral distance, and the lateral distance falls within a range of 1.5 times to 1.8 times the vertical distance.

25. The semiconductor package according to claim 24, wherein the lateral distance is not less than 0.8 microns.

26. The semiconductor package according to claim 18, wherein the first die and the second die respectively have an interface circuit disposed therein, and the interface circuit of the first die and the interface circuit of the second die are in signal communication through the redistribution structure.

27. The semiconductor package according to claim 18, further comprising a package substrate, wherein a side of the substrate structure opposite to the redistribution structure is bonded to the package substrate.

28. The semiconductor package according to claim 18, wherein the redistribution structure further comprises a plurality of signal wirings, a plurality of shielding wirings, and a plurality of underlayer wirings, the underlayer wirings are disposed on the substrate, and the signal wirings and the shielding wirings are located between the underlayer wirings and the pad-connection layer, wherein the underlayer wirings have a same width.

29. The semiconductor package according to claim 28, the underlayer wirings comprise a plurality of ground wirings and a plurality of power source wirings, wherein the ground wirings and the power source wirings are alternately disposed in a lateral direction, each of the ground wirings and one of the signal wirings are correspondingly disposed in a vertical direction, and each of the power source wirings and one of the shielding wirings are correspondingly disposed in the vertical direction.
